(19) United States
(12) Patent Application Publication
(10) Pub. No.: US 2026/0173759 A1
(43) Pub. Date: Jun. 18, 2026

(54) METHOD OF IMPLANTING ATOMIC SPECIES INTO A PIEZOELECTRIC SUBSTRATE

(71) Applicant: Soitec, BERNIN (FR)

(72) Inventor: Cédric Charles-Alfred, Grenoble (FR)

(21) Appl. No.: 18/575,555

(22) PCT Filed: Jul. 19, 2022
(86) PCT No.: PCT/EP2022/070204

§ 371 Date: Dec. 29, 2023

(30) Foreign Application Priority Data
Jul. 19, 2021 (FR) FR2107785

(51) Int. Cl. H10N 30/04; H10N 30/08

(52) U.S. Cl. CPC H10N 30/04; H10N 30/08

(57) ABSTRACT

A method of implanting atomic species into a piezoelectric substrate comprises providing a substrate including a piezoelectric portion and an electrically conductive portion mounting the substrate with the electrically conductive portion over a chuck, and implanting atomic species into the piezoelectric portion.

### CROSS-REFERENCE TO RELATED APPLICATIONS

This application is a national phase entry under 35 U.S.C. § 371 of International Patent Application PCT/EP2022/070204, filed Jul. 19, 2022, designating the United States of America and published as International Patent Publication WO 2023/001827 A1 on Jan. 26, 2023, which claims the benefit under Article 8 of the Patent Cooperation Treaty of French Patent Application Serial No. FR 2107785, filed Jul. 19, 2021.

### TECHNICAL FIELD

The present disclosure relates to a method of implanting atomic species into a piezoelectric substrate, more particularly, to a high density implantation into bulk piezoelectric substrates.

### BACKGROUND

The fabrication of piezoelectric on insulator wafers (POI) requires the use of an implantation process, in particular, of a high density implantation process.

The implanting of ions takes place in an implanting device in which a number of substrates are subjected to an ion beam. To implant over the entire surface, the substrates are mounted on a rotating and/or translating implantation wheel so that the entire surface of the substrate passes under the ion beam. Maintaining means, such as clips, are used to fix the substrate on the implanting wheel against the rotational forces. Usually, the maintaining means are fixed metallic restraints that are also configured to drain electrical charges generated during the ion implantation.

A high density implantation process results in the accumulation of charges in the piezoelectric substrate to be implanted. At the same time, a high temperature gradient is observed in the substrate during implantation leading to a deformation in the form of bow and warp of the piezoelectric substrate. Consequently, charges and heat cannot be sufficiently dissipated into a metallic chuck used in the implantation chamber. To remedy this problem, the piezoelectric substrate is placed on an elastomer layer provided over the metallic chuck. This elastomer layer provides a thermal contact between the piezoelectric substrate and the chuck. The fixed metallic restraints are used to provide an electrical contact between the piezoelectric substrate and the chuck. The electrical contact obtained, however, is only a localized contact between the piezoelectric substrate and the chuck.

Breakage of piezoelectric substrates is still observed, however, which is attributed to an insufficient evacuation of charges.

Therefore, the charge dissipation out from a piezoelectric substrate needs to be further improved.

### BRIEF SUMMARY

The object of the present disclosure is achieved by a method of implanting atomic species into a piezoelectric substrate, comprising the steps of a) providing a substrate comprising a piezoelectric portion and an electrically conductive portion, b) mounting the substrate with the electrically conductive portion over a chuck, and c) implanting atomic species into the piezoelectric portion.

As explained above, the implantation is performed into the piezoelectric portion and results in an accumulation of charges in the piezoelectric portion. The use of an electrically conductive portion in the substrate to be implanted, however, results in an improved evacuation of the charges from the piezoelectric portion as the charges can easier accumulate outside the piezoelectric portion thereby reducing stress and reducing the risk of breakage.

According to a variant, the step b) can comprise providing an elastomer layer between the chuck and the electrically conductive portion of the substrate. Thus, the electrically conductive portion of the substrate is isolated from the chuck.

According to a variant of the present disclosure, the step a) can comprise attaching a piezoelectric substrate forming the piezoelectric portion to an electrically conductive substrate forming the electrically conductive portion of the substrate. Attaching two substrates together, e.g., via molecular adhesion, is a reliable attachment process.

According to a variant of the present disclosure, the step a) can further comprise a step of thinning the piezoelectric substrate to obtain a piezoelectric layer, in particular, with a thickness between 1 μm and 100 μm. Thinning of the piezoelectric substrate reduces the length of the path for charges must travel to reach the electrically conductive portion. Thus, the accumulation of charges can be even further reduced.

According to a variant of the present disclosure, the piezoelectric substrate and the electrically conductive substrate are chosen such that the difference in thermal expansion coefficients is less than 50*10⁻⁶K⁻¹, preferably less than 20*10⁻⁶K⁻¹. By matching the thermal expansion coefficients, the use of an electrically conductive substrate with thermal expansion parameters, which fit the thermal expansion parameters of the piezoelectric substrate provides a substrate that will withstand thermal gradients without breaking up or showing damage at the interface between the piezoelectric substrate and the electrically conductive substrate.

According to a variant of the present disclosure, the step of attaching the electrically conductive substrate with the piezoelectric substrate is realized using a bonding layer between the two substrates. The use of a bonding layer provides a wider choice of suitable materials for the electrically conductive substrate and the piezoelectric substrates.

According to a variant of the present disclosure, the bonding layer can be a conductive bonding layer, in particular, a metallic layer. Again, this results in a more versatile process, with a higher degree of freedom to choose the electrically conductive substrate. Indeed, the bonding layer can also improve the evacuation of charges from the piezoelectric substrate toward the electrically conductive substrate, even when a low electrically conductive substrate is used as the electrically conductive substrate.

According to a variant of the present disclosure, the step of providing the electrically conductive portion can comprise providing one or more cavities in the side of the substrate facing the chuck and filling the one or more cavities with a conductive material, in particular, a metal.

Providing filled metallic cavities in the bottom portion of the piezoelectric substrate results in an improved conductivity in this portion of the piezoelectric substrate. Thus, the evacuation of charges from the piezoelectric substrate is improved as the path toward a portion with higher conductivity is reduced.

According to a variant, the piezoelectric substrate is a bulk piezoelectric substrate, in particular, a bulk piezoelectric wafer. Using the electrically conductive portion allows for implantation into piezoelectric materials even for thicknesses of the piezoelectric material of more than 20 μm, in particular, more than 100 μm.

According to a variant of the present disclosure, the substrate can have a conductivity of 10⁻⁴ S/cm or more. In this context, an electrically conductive portion can be realized using a metallic or semiconductor material. Preferred materials are e.g., a silicon substrate, or a metallic substrate, e.g., a molybdenum, aluminum, or tungsten substrate.

According to a variant, the step b) can be realized such that the electrically conductive portion and/or the bonding layer is/are in electrical contact with at least one metallic restraint electrically connected with the chuck. Due to the electrical connection between the electrically conductive portion and/or the bonding layer of the substrate, the charges accumulated within the piezoelectric portion can move out of the piezoelectric portion and be evacuated by the metallic restraint. This evacuation of charges reduces the risk of the occurrence of substrate deformation and high stress and therefore reduces the risk of breakage.

According to a variant, in step c) a predetermined splitting area can be provided in the piezoelectric portion and the method can further comprise a step d) of attaching the piezoelectric portion of the piezoelectric substrate to a handle substrate and step e) of detaching the remainder of the piezoelectric substrate at the predetermined splitting area to transfer a layer of the piezoelectric substrate onto the handle substrate. With this method, piezoelectric on insulator substrates (POI) can be realized that have a reduced number of defects that might occur due to stress during the implantation step.

### BRIEF DESCRIPTION OF THE DRAWINGS

The present disclosure may be understood by reference to the following description taken in conjunction with the accompanying figures, in which reference numerals identify features of embodiments of the present disclosure.

FIG. 1 schematically illustrates a method of implanting atomic species into a bulk piezoelectric substrate according to a first embodiment of the present disclosure.

FIG. 2 schematically illustrates a method of implanting atomic species into a bulk piezoelectric substrate according to a variant of the first embodiment of the present disclosure.

FIG. 3 schematically illustrates schematically a method of implanting atomic species into a bulk piezoelectric substrate according to a second embodiment of the present disclosure.

### DETAILED DESCRIPTION

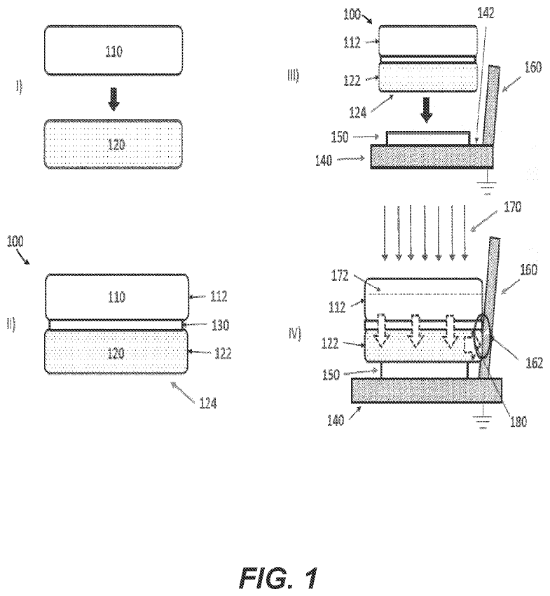

FIG. 1 schematically illustrates a method of implanting atomic species into a piezoelectric substrate 100 according to the first embodiment of the present disclosure.

The method comprises a first step I), corresponding to step a) of the inventive method, of providing a piezoelectric substrate 110 and an electrically conductive substrate 120.

The piezoelectric substrate 110 in this embodiment is a bulk piezoelectric substrate, e.g., a bulk piezoelectric wafer between 200 μm and 700 μm thick. The present disclosure relates to piezoelectric materials such as LiTaO₃, LiNbO₃, Quartz, BaTiO₃, Pb(ZrₓTi₁₋ₓ)O₃, GaPO₄, GaAsO₄, AlPO₄, FePO₄, PbTiO₃, KNbO₃, BiFeO₃, Pb(Zn_{1/3}Nb_{2/3})₁₋ₓTiₓO₃, Pb(Mg_{1/3}Nb_{2/3})₁₋ₓTiₓO₃, Pb(Sc_{1/2}Nb_{1/2})₁₋ₓTiₓO₃. In general, the electrical conductivity of piezoelectric substrates 110 is low, on the order of 10-11S/cm or less.

The electrically conductive substrate 120 can be a semiconductor substrate, e.g., a silicon substrate, or a metallic substrate, e.g., a molybdenum, aluminum, or tungsten substrate. Semiconductor substrates are interesting as they are in line with the production line specifications in terms of metallic contamination. Metals have a higher conductivity but have to be chosen such that they satisfy the metallic contamination specifications of the fabrication line.

The electrically conductive substrate 120 has a conductivity that is higher than the conductivity of the piezoelectric substrate 110 on the order of 10-4S/cm or more.

Furthermore, the material of the electrically conductive substrate 120 is chosen such that its thermal expansion coefficient matches the one of the piezoelectric substrate 110 as will be explained later. Preferably, the difference in the thermal expansion coefficient is less than 20*10⁻⁶K⁻¹.

Next, the piezoelectric substrate 110 is attached to the electrically conductive substrate 120 to form a substrate 100, as illustrated by step II). The substrate 100 comprises a piezoelectric portion 112, realized by a piezoelectric substrate 110 and an electrically conductive portion 122, realized by the electrically conductive substrate 120.

In this embodiment, the piezoelectric substrate 110 is attached to the electrically conductive substrate 120 using a bonding layer 130.

The bonding layer 130 can be an electrically conductive layer or a non conductive layer. For example, the bonding layer 130 can be a metallic layer, which would provide a higher degree of freedom when choosing the electrical conductive substrate 120.

Before attaching the two substrates, the bonding layer 130 can be provided on either the piezoelectric substrate 110 or on the electrically conductive substrate 120 by a process known in the art. In a variant, a bonding layer could be provided on each one of the piezoelectric substrate 110 and the electrically conductive substrate 120. One or more additional layers could be present between the piezoelectric substrate 110 and the electrically conductive substrate 120. For example, a thin SiO₂ layer or a trap rich layer to further improve the electrical and thermal properties.

In an alternative, the step II) of attaching can also be a direct bonding step, where the piezoelectric substrate 110 is directly attached to the electrically conductive substrate 120, for example, via molecular adhesion bonding.

A temperature treatment can follow the attachment step between the piezoelectric substrate 110 and the electrically conductive substrate 120 to strengthen the bond between the two substrates.

Next, the substrate 100 is mount on a chuck 140 of an atomic species implanter, as illustrated by step III), corresponding to step b) according to the inventive method.

The substrate 100 is mount on the chuck 140 via its main surface 124, which is the free surface of the electrically conductive substrate 120. The main surface 124 is the free main surface of the electrically conductive substrate opposite to the surface where attachment occurred.

As illustrated, the substrate 100 is not directly mount onto the chuck 140 but on an elastomer layer 150 previously provided on the surface 142 of the chuck 140. The elastomer layer 150 is, for example, a silicone matrix such as PDMS (Polydimethyl Siloxane), and has a thickness of 50 μm to 500 μm. The elastomer layer 150 is used to compensate for deformations of the substrate 100, like bow and warp, during the subsequent implantation step. As described above, the elastomer layer 150 furthermore provides a thermal contact between the substrate 100 and the metallic chuck 140 to allow heat dissipation.

The chuck 140 further comprises one or more metallic restraints 160 to keep the substrate 100 in place when the chuck 140 rotates with the implantation wheel (not shown).

Following the positioning of the substrate 100 on the elastomer layer 150, ions 170 are implanted into the substrate 100 as illustrated in step IV), corresponding to step c) of the inventive method. Typical atomic species are hydrogen or a noble gas, such as helium.

The ion implantation is used to form a mechanically weakened layer 172 inside the piezoelectric portion 112. This mechanically weakened layer 172 may serve as a predetermined splitting area in a subsequent layer transfer process to obtain a so called piezoelectric-oninsulator (POI) substrate.

The ions 170 are implanted using a high density implantation process with ion beam currents on the order of 1 mA to 25 mA.

Since the ions 170 are implanted into the piezoelectric portion 112 of the substrate 100, and since the piezoelectric portion 112 has a low conductivity, the piezoelectric portion 112 of the substrate 100 would have suffered from accumulation of charges during the ion implantation process as described above with respect to the state of the art. Due to the presence of the electrically conductive portion 122 and/or the bonding layer 130 of the substrate 100 according to the present disclosure, those charges can move out of the piezoelectric portion 112, which reduces the risk of the occurrence of substrate deformation and high stress and therefore reduces the risk of breakage.

In addition, the matching of the thermal expansion coefficients of the piezoelectric portion 112 with respect to the electrically conductive portion 122 reduces stress inside the substrate and reduces or even prevents the occurrence of cracks or defects inside the substrate 100, especially at the interface between the electrically conductive portion 122 and the piezoelectric portion 112.

The electrically conductive portion 122 and/or the bonding layer 130 is/are in electrical contact 162 with the one or more metallic restraints 160. Thus, once the electrical charges 180 have entered the electrically conductive portion 122 and/or the bonding layer 130, the charges 180 are evacuated via the one or more metallic restraints 160 and the chuck 140, which is grounded.

Preferably, the chuck 140 and the one or more metallic restraint 160 are made of the same metallic material, in particular, aluminum.

Thus, using the substrate 100 according to the present disclosure, the inventive implantation process provides an improved evacuation of charges compared to the state of the art implantation process.

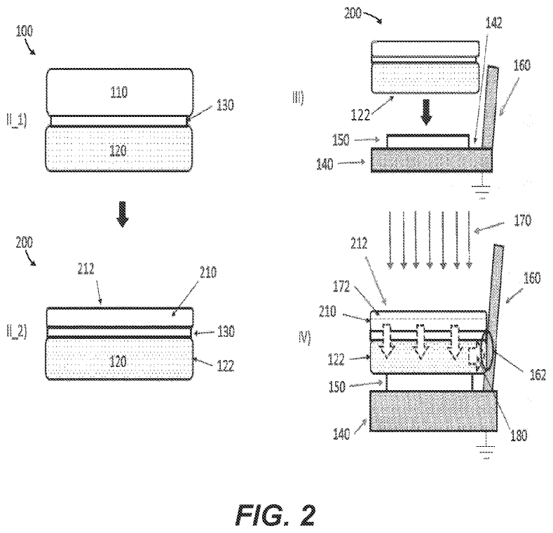

FIG. 2 illustrates a variant of the first embodiment. In this embodiment, steps I) and II) are the same as in the first embodiment and therefore are not described again, reference being made to their description above. After the step II) of attaching the piezoelectric substrate 110 and the electrically conductive substrate 120, an additional process step II_2) of thinning the piezoelectric substrate 110 of the substrate 100 is performed to obtain a modified substrate 200.

This step of thinning can be performed using a mechanical process or a chemical etching process such as those known in the art and adapted to piezoelectric substrates. The thinning step may be accompanied by further process steps, such as polishing after the thinning step to improve the quality of the surface 212 of the thinned piezoelectric portion 210.

The thinned piezoelectric portion 210 is thinned down to a thickness of about 100 μm to 1 μm.

Steps III) and IV) are then realized in the same way as described above, except that modified substrate 200 with the thinned piezoelectric portion 210 is used instead of substrate 100. Reference is therefore made to the description of steps III) and IV) above with reference to FIG. 1.

The implanted ions 170 form a predetermined mechanically weakened layer 172 and charges 180 are evacuated via the bonding layer 130 and/or the electrically conductive portion 122.

The thinning of the piezoelectric substrate 110 further improves the evacuation of charges 180 out of the piezoelectric portion 210.

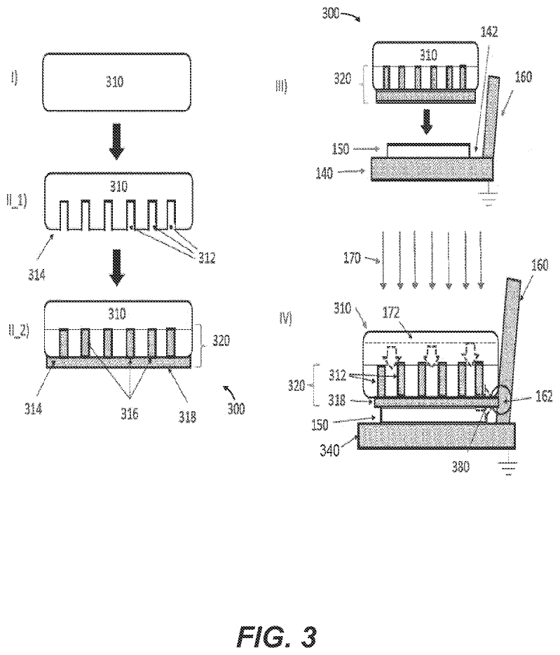

According to a second embodiment, as shown in FIG. 3, the substrate 300 is realized without attaching a piezoelectric substrate to an electrically conductive substrate. In this embodiment, only a piezoelectric substrate 310 is provided, see step I) in FIG. 3. This piezoelectric substrate 310 has the same properties as the piezoelectric substrate 110 described above.

Subsequently, during step II_1) one or more cavities 312 are formed in one main surface 314 of the piezoelectric substrate 310 using patterning and etching steps as known in the art. According to an example, the cavities 312 can form a regular pattern or matrix and can all be of the same size.

Then, as illustrated by step II_2) the cavities 312 are filled with a conductive material 316, in particular, a metal, using a deposition process as known in the art to form the electrically conductive portion 320. The deposition process can be/is carried out such that a conductive layer 318 is realized on the main surface 314 to interconnect the conductive material 316 in each of the cavities 312. The part of the substrate 300 comprising the conductive material 316 inside the cavities 312 and the layer 318 forms the electrically conductive portion 320 according to the present disclosure.

Subsequently, step III) of positioning on an implanter wheel and step IV) of implanting ions 170 are realized like in the first embodiment using the same chuck 140 with the elastomer layer 150 and the metallic restraint 160. Their description will therefore not be repeated again, but reference is made to the description of FIGS. 1 and 2.

In this embodiment, the charges are collected via the matrix of filled cavities 312 and the evacuation of the charges 380 is realized via the layer 318, which is in contact 162 with the metallic restraint 160, from the piezoelectric portion 310 toward the electrically conductive portion 320.

Thanks to the improved conductivity of the substrate 300 comprising the cavities 312 filled with conductive material 316, thereby forming the electrically conductive portion 320 of the substrate 300, the charges can be evacuated from the piezoelectric portion 310 through the electrically conductive portion 320 to the grounded chuck 340.

The inventive piezoelectric substrate 100, 200 or 300 can be used as a donor substrate in a subsequent layer transfer process to transfer a thin layer of the piezoelectric material onto a handle substrate to thereby form a piezoelectric-on-insulator (POI) substrate. In such a process, the inventive piezoelectric substrate 100, 200 or 300 is attached with the surface of the piezoelectric substrate 110, 210, 310, e.g., by bonding, to a handle substrate, e.g., a silicon wafer with or without additional layers on the surface at which bonding takes place. The transfer of the piezoelectric layer then occurs at the mechanically weakened layer 172 inside the piezoelectric substrate 110, 210, 310 by applying a thermal or mechanical load.

A number of embodiments of the present disclosure have been described. Nevertheless, it is understood that various modifications and enhancements may be made without departing from the invention as defined by the following claims.

1. A method of implanting atomic species into a piezoelectric substrate, comprising:
providing a substrate comprising a piezoelectric portion and an electrically conductive portion;
mounting the substrate with the electrically conductive portion over a chuck; and
implanting atomic species into the piezoelectric portion

2. The method of claim 1, wherein mounting the substrate with the electrically conductive portion over the chuck comprises providing an elastomer layer between the chuck and the electrically conductive portion, of the substrate

3. The method of claim 1, wherein providing the substrate comprises attaching a piezoelectric substrate including the piezoelectric portion to an electrically conductive substrate including the electrically conductive portion of the substrate.

4. The method of claim 3, wherein providing the substrate further comprises thinning the piezoelectric substrate to obtain a piezoelectric layer.

5. The method of claim 3, wherein the piezoelectric substrate and the electrically conductive substrate are chosen such that a difference in thermal expansion coefficients of the piezoelectric substrate and the electrically conductive substrate is less than 50*10⁻⁶K⁻¹.

6. The method of claim 3, wherein the step of attaching the electrically conductive substrate with the piezoelectric substrate is realized using a bonding layer between the piezoelectric substrate and the electrically conductive substrate.

7. The method of claim 6, wherein the bonding layer is a conductive bonding layer.

8. The method of claim 1, wherein the step of providing the electrically conductive portion comprises providing one or more cavities in a side of the substrate facing the chuck and filling the one or more cavities with a conductive material.

9. The method of claim 1, wherein the piezoelectric substrate is a bulk piezoelectric substrate.

10. The method of claim 1, wherein the substrate has a conductivity of 10⁻⁴ S/cm or more.

11. The method of claim 1, where mounting the substrate with the electrically conductive portion over the chuck performed such that the electrically conductive portion and/or the bonding layer is/are in electrical contact with at least one metallic restraint electrically connected with the chuck.

12. The method of claim 1, where during the implanting of the atomic species into the piezoelectric portion, a predetermined splitting area is formed in the piezoelectric portion, the method further comprising a attaching the piezoelectric portion of the piezoelectric substrate to a handle substrate, and detaching a remainder of the piezoelectric substrate at the predetermined splitting area to transfer a layer of the piezoelectric substrate onto the handle substrate.

13. The method of claim 4, wherein thinning the piezoelectric substrate comprises thinning the piezoelectric layer to a thickness between 1 μm and 100 μm.

14. The method of claim 5, wherein the piezoelectric substrate and the electrically conductive substrate are chosen such that a difference in thermal expansion coefficients of the piezoelectric substrate and the electrically conductive substrate is less than 20*10⁻⁶K⁻¹.

15. The method of claim 7, wherein the bonding layer is a metallic layer.

16. The method of claim 8, wherein filling the one or more cavities with a conductive material comprises filling the one or more cavities with a metal.

17. The method of claim 9, wherein the bulk piezoelectric substrate is a bulk piezoelectric wafer.

18. The method of claim 17, wherein the bulk piezoelectric wafer has a thickness of more than 20 μm.

19. The method of claim 18, wherein the bulk piezoelectric wafer has a thickness of more than 100 μm.

20. The method of claim 2, wherein providing the substrate comprises attaching a piezoelectric substrate including the piezoelectric portion to an electrically conductive substrate including the electrically conductive portion of the substrate.
